(19) United States
(12) Patent Application Publication
(10) Pub. No.: US 2026/0276686 A1
(43) Pub. Date: Sep. 17, 2026

(54) UTILITY METER WITH DIGITAL INPUTS AND SYNCHRONIZATION CIRCUIT

(71) Applicant: EI ELECTRONICS LLC, D/B/A ELECTRO INDUSTRIES/GAUGE TECH, Westbury, NY (US)

(72) Inventors: Tibor Banhegyesi, Northport, NY (US); Jorge Arturo Polar Seminario, Winter Park, FL (US)

(21) Appl. No.: 19/567,958

(22) Filed: Mar. 16, 2026

Related U.S. Application Data
(60) Provisional application No. 63/773,013, filed on Mar. 17, 2025.

(51) Int. Cl. G01R 22/10; G01R 15/24; G01R 19/175; G01R 19/25

(52) U.S. Cl. CPC G01R 22/10; G01R 15/247; G01R 19/175; G01R 19/2509; G01R 19/2513

(57) ABSTRACT

A utility meter includes a housing and at least one sensor connected to the housing and configured to be connected to a utility system. The utility meter includes a processing system having one or more processors. The utility meter can utilize a current regulating circuit to provide proper voltage output to the various components. The utility meter can also utilize a zero-crossing detector circuit configured to produce a zero-crossing signal for a three-phase power supply.

### RELATED APPLICATION(S)

This application is based on U.S. Provisional Application Ser. No. 63/773,013, filed Mar. 17, 2025, the disclosure of which is incorporated herein by reference in its entirety and to which priority is claimed.

### FIELD

The present disclosure is directed to intelligent electronic devices for utility systems, such as smart meters that can record and communicate utility usage information.

### BACKGROUND

Monitoring of electrical energy by consumers and providers of electric power is a fundamental function within any electric power distribution system. Electrical energy may be monitored for purposes of usage, equipment performance and power quality. Electrical parameters that may be monitored include volts, amps, watts, vars, power factor, harmonics, kilowatt hours, kilovar hours and any other power related measurement parameters. Typically, measurement of the voltage and current at a location within the electric power distribution system may be used to determine the electrical parameters for electrical energy flowing through that location.

Devices that perform monitoring of electrical energy may be electromechanical devices, such as, for example, a residential billing meter or may be an intelligent electronic device (“IED”). Intelligent electronic devices typically include some form of a processor. In general, the processor is capable of using the measured voltage and current to derive the measurement parameters. The processor operates based on a software configuration. A typical consumer or supplier of electrical energy may have many intelligent electronic devices installed and operating throughout their operations. IEDs may be positioned along the supplier's distribution path or within a customer's internal distribution system. IEDs include revenue electric watt-hour meters, protection relays, programmable logic controllers, remote terminal units, fault recorders and other devices used to monitor and/or control electrical power distribution and consumption. IEDs are widely available that make use of memory and microprocessors to provide increased versatility and additional functionality. Such functionality includes the ability to communicate with remote computing systems, either via a direct connection, e.g., a modem, a wireless connection or a network. IEDs also include legacy mechanical or electromechanical devices that have been retrofitted with appropriate hardware and/or software allowing integration with the power management system.

Typically, an IED is associated with a particular load or set of loads that are drawing electrical power from the power distribution system. The IED may also be capable of receiving data from or controlling its associated load. Depending on the type of IED and the type of load it may be associated with, the IED implements a power management function that is able to respond to a power management command and/or generate power management data. Power management functions include measuring power consumption, controlling power distribution such as a relay function, monitoring power quality, measuring power parameters such as phasor components, voltage or current, controlling power generation facilities, computing revenue, controlling electrical power flow and load shedding, or combinations thereof.

Conventional IEDs include the ability to communicate with remote computing systems. Traditionally, IEDs would transfer data using serial based download commands. These commands would be accessed via an RS232, and RS485 or an Ethernet port encapsulating the serial request with an Ethernet message using any Ethernet protocol such as HTTP or TCP/IP. For instance, host software would make a request for a set of data from one or more memory registers in an IED. At that point, the IED would then communicate the data stored in the memory registers back to the host software utilizing a serial transfer. A need exists for systems and methods for efficiently collecting data from various devices, e.g., IEDs. A further need exists for systems and methods for analyzing and reporting such collected data.

### SUMMARY

In certain implementations, the IED can utilize a current regulating circuit to provide proper voltage output to the various components.

In certain implementations, the IED can utilize a multiplexer which receives the input from each phase from a multi-phase power supply (Va, Vb, Vc, phases).

In certain implementations, the IED can utilize a zero-crossing detector circuit configured to produce a zero-crossing signal for a three-phase power supply.

In certain implementations, the IED can utilize a current regulating circuit to provide proper voltage output to the various components and a multiplexer which receives the input from each phase from a multi-phase power supply (Va, Vb, Vc, phases).

In certain configurations, a utility meter includes a housing and at least one sensor connected to the housing and configured to be connected to a utility system. The at least one sensor is configured for measuring at least one parameter of the utility system and generating at least one analog signal indicative of the at least one parameter. At least one analog to digital converter is connected to the at least one sensor. The at least one analog to digital converter is configured to receive the at least one analog signal and convert the at least one analog signal to an at least one digital signal to obtain measured data. A processing system includes one or more processors. The processing system configured for receiving the at least one digital signal. An input port is configured to receive a digital input from an external device. An input regulator is configured to receive the digital input and condition the digital input. The input regulator includes a current regulator circuit.

In certain configurations, a utility meter includes a housing and at least one sensor connected to the housing and configured to be connected to a utility system, The at least one sensor is configured for measuring at least one parameter of the utility system and generating at least one analog signal indicative of the at least one parameter. At least one analog to digital converter is connected to the at least one sensor. The at least one analog to digital converter is configured to receive the at least one analog signal and convert the at least one analog signal to an at least one digital signal to obtain measured data. A processing system includes one or more processors. The processing system configured for receiving the at least one digital signal. A zero-crossing circuit is in communication with the processing system. The zero-crossing circuit includes a multiplexer circuit configured to receive a three-phase input and produce a single multiplexer output.

In certain implementations, a method of conditioning a digital input signal for a utility meter includes receiving, at a utility meter having a housing and a processing system, a digital input having an input current and input voltage. The input current and input voltage are conditioned via a regulator circuit using a current regulator to create a regulated input. A digital output is transmitted to the processing system.

Certain implementations are directed to a method of determining a zero-crossing event from a 3-phase voltage signal in a utility meter. A three-phase power input having an input voltage and an input frequency is received. The first phase and the second phase are input into a first multiplexer. The first multiplexer selects one of the first phase and the second phase as a first output. The first output and the third phase are input into a second multiplexer. The second multiplexer selects one of the third phase and the first output as a multiplexer output. The multiplexer output is provided to a comparator to obtain a zero-crossing signal. The zero-crossing signal is provided to a processing system.

### BRIEF DESCRIPTION OF THE DRAWINGS

The aspects and features of various exemplary embodiments will be more apparent from the description of those exemplary embodiments taken with reference to the accompanying drawings.

FIG. 1 is a block diagram of an intelligent electronic device (IED).

FIG. 2 is a circuit schematic of an exemplary input regulator circuit.

FIG. 3 is a circuit schematic of an exemplary multiplexer circuit.

FIG. 4 is a circuit schematic of an exemplary bandpass filter.

FIG. 5 is a circuit schematic of an exemplary comparator.

FIG. 6 is a circuit schematic of an exemplary high-pass filter.

FIG. 7 is a circuit schematic of an exemplary set of low-pass filters.

FIG. 8 is a circuit schematic of an exemplary comparator and voltage buffer.

### DETAILED DESCRIPTION OF EXEMPLARY EMBODIMENTS

In certain implementations, intelligent electronic devices (“IEDs”) sense electrical parameters and compute data and can be any device including, but not limited to, Programmable Logic Controllers (“PLC's”), Remote Terminal Units (“RTU's”), electric power meters, panel meters, protective relays, fault recorders, phase measurement units, serial switches, smart input/output devices and other devices which are coupled with power distribution networks to manage and control the distribution and consumption of electrical power. A meter is a device that records and measures power events, power quality, current, voltage waveforms, harmonics, transients and other power disturbances. Revenue accurate meters (“revenue meter”) relate to revenue accuracy electrical power metering devices with the ability to detect, monitor, report, quantify and communicate power quality information about the power that they are metering.

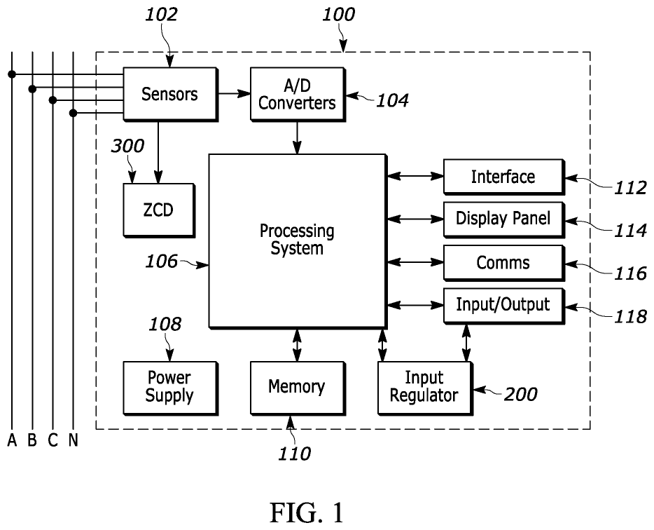

FIG. 1 shows an exemplary configuration of an IED 100 having a plurality of sensors 102 connected to various phases A, B, C and neutral N of an electrical distribution system. One or more analog-to-digital (A/D) converters 104 can be connected to the sensors and connect the sensors 102 to a processing system 106. The processing system 106 can include any combination of processing components including, a CPU, microcontroller, digital signal processors, field programmable gate arrays, programmable logic device, etc. The IED 100 can include a power supply 108 to supply power to the various components. One or more memory units 1110 is connected to the processing system 106. The processing system 106 can be in communication with a user interface 112, a display panel 114, a communication interface 116, and one or more input/output ports 118.

The plurality of sensors 102 sense electrical parameters, e.g., voltage and current, on incoming lines, (i.e., phase A, phase B, phase C, neutral N), from an electrical power distribution system. In certain configurations, the sensors 102 can include current transformers and potential transformers, wherein one current transformer and one voltage transformer will be coupled to each phase of the incoming power lines. A primary winding of each transformer will be coupled to the incoming power lines and a secondary winding of each transformer will output a voltage representative of the sensed voltage and current.

The output of each transformer will be coupled to the A/D converters 104 configured to convert the analog output voltage from the transformer to a digital signal that can be processed by the processing system 106. A/D converters 104 are respectively configured to convert an analog voltage output to a digital signal that is transmitted to the processing system 106 to be processed. The processing system 106 is configured to operatively receive digital signals from the A/D converters 104 and to perform calculations necessary to determine power usage and to control the overall operations of the IED 100.

The power supply 108 provides power to each component of the IED 100. In certain configurations, the power supply 108 is a transformer with its primary windings coupled to the incoming power distribution lines and having windings to provide a nominal voltage, e.g., 5 VDC, +12 VDC and −12 VDC, at its secondary windings. In other configurations, power may be supplied from an independent power source to the power supply 108. For example, power may be supplied from a different electrical circuit or an uninterruptible power supply (UPS). In other configurations, the power supply can be a DC power supply such as a battery or rechargeable battery.

In some configurations, the power supply 108 can be a switch mode power supply in which the primary AC signal will be converted to a form of DC signal and then switched at high frequency, such as, for example, 100 Khz, and then brought through a transformer to step the primary voltage down to, for example, 5 Volts AC. A rectifier and a regulating circuit would then be used to regulate the voltage and provide a stable DC low voltage output. Other embodiments, such as, but not limited to, linear power supplies or capacitor dividing power supplies are also contemplated.

The IED 100 further comprises a memory unit 110 which can include one or more memory components, such as volatile memory and non-volatile memory. In addition to storing audio and/or video files, memory 110 can store the sensed and generated data for further processing and for retrieval when called upon to be displayed at the IED 100 or from a remote location. The memory 110 can include any combination of: internal storage memory, e.g., random access memory (RAM); removable memory such as magnetic storage memory; optical storage memory, e.g., the various types of CD and DVD media; solid-state storage memory, e.g., a CompactFlash card, a Memory Stick, SmartMedia card, MultiMediaCard (MMC), SD (Secure Digital) memory; or any other memory storage that exists currently or will exist in the future. By utilizing removable memory, an IED can be easily upgraded as needed. Such memory will be used for storing historical trends, waveform captures, event logs including time-stamps and stored digital samples for later downloading to a client application, web-server or PC application.

The user interface 112 is connected to the processing system 106 for interacting with a user and for communicating events, such as alarms and instructions to the user. The interface 112 may include any set of physical inputs, such as buttons, touch screens, dials, etc. The user interface 112 further includes a speaker or audible output means for audibly producing instructions, alarms, data, etc. The speaker is coupled to the processing system 106 via a digital-to-analog converter (D/A) for converting digital audio files stored in memory 110.

The IED 100 can also include a display 114 for providing visual indications to the user. The display may be embodied as a touch screen, a liquid crystal display (LCD), a plurality of LED number segments, individual light bulbs or any combination. The display 114 can provide information to the user in the form of alpha-numeric lines, computer-generated graphics, videos, animations, etc. In certain configurations, the IED 100 can also support various media file types.

In certain implementations, the IED 100 will include a communication device 116, also know as a network interface, for enabling communications between the IED or meter, and a remote terminal unit, programmable logic controller and other computing devices, microprocessors, a desktop computer, laptop computer, other meter modules, etc. The communication device 116 can be a modem, network interface card (NIC), wireless transceiver, etc. The communication device 116 will perform its functionality by hardwired and/or wireless connectivity. The hardwire connection may include but is not limited to hard wire cabling e.g., parallel or serial cables, RS232, RS485, USB cable, Firewire (1394 connectivity) cables, Ethernet, and the appropriate communication port configuration. The wireless connection will operate under any of the various wireless protocols including but not limited to Bluetooth™ interconnectivity, infrared connectivity, radio transmission connectivity including computer digital signal broadcasting and reception commonly referred to as Wi-Fi or 802.11.X (where x denotes the type of transmission), satellite transmission or any other type of communication protocols, communication architecture or systems currently existing or to be developed for wirelessly transmitting data including spread spectrum 900 MHz, or other frequencies, Zigbee, WiFi, or any mesh enabled wireless communication.

The IED 100 can communicate to a server or other computing device via the communication device 116. The IED 100 can be connected to a communications network, e.g., the Internet, by any means, for example, a hardwired or wireless connection, such as dial-up, hardwired, cable, DSL, satellite, cellular, PCS, wireless transmission (e.g., 802.11a/b/g), etc. It is to be appreciated that the network may be a local area network (LAN), wide area network (WAN), the Internet or any network that couples a plurality of computers to enable various modes of communication via network messages. Furthermore, the server will communicate using various protocols such as Transmission Control Protocol/Internet Protocol (TCP/IP), File Transfer Protocol (FTP), Hypertext Transfer Protocol (HTTP), etc. and secure protocols such as Hypertext Transfer Protocol Secure (HTTPS), Internet Protocol Security Protocol (IPSec), Point-to-Point Tunneling Protocol (PPTP), Secure Sockets Layer (SSL) Protocol, etc. The server will further include a storage medium for storing a database of instructional videos, operating manuals, etc., the details of which will be described in detail below.

In an additional configuration, the IED 100 can also have the capability of not only digitizing waveforms, but storing the waveform and transferring that data upstream to a central computer, e.g., a remote server, when an event occurs such as a voltage surge or sag or a current short circuit. This data will be triggered and captured on an event, stored to memory, e.g., non-volatile RAM, and additionally transferred to a host computer within the existing communication infrastructure either immediately in response to a request from a remote device or computer to receive said data in response to a polled request. The digitized waveform will also allow the processing system 106 to compute other electrical parameters such as harmonics, magnitudes, symmetrical components and phasor analysis. Using the harmonics, the IED 10 will also calculate dangerous heating conditions and can provide harmonic transformer derating based on harmonics found in the current waveform.

In a further configuration, the IED 100 can execute an e-mail client and will send e-mails to the utility or to the customer direct on an occasion that a power quality event occurs. This allows utility companies to dispatch crews to repair the condition. The data generated by the meters are used to diagnose the cause of the condition. The data is transferred through the infrastructure created by the electrical power distribution system. The email client will utilize a POP3 or other standard mail protocol. A user will program the outgoing mail server and email address into the meter.

The techniques of the present disclosure can be used to automatically maintain program data and provide field wide updates upon which IED firmware and/or software can be upgraded. An event command can be issued by a user, on a schedule or by digital communication that will trigger the IED 100 to access a remote server and obtain the new program code. This will ensure that program data will also be maintained allowing the user to be assured that all information is displayed identically on all units.

It is to be understood that the present disclosure may be implemented in various forms of hardware, software, firmware, special purpose processors, or a combination thereof. The IED 100 also includes an operating system and micro instruction code. The various processes and functions described herein may either be part of the micro instruction code or part of an application program (or a combination thereof) which is executed via the operating system.

It is to be further understood that because some of the constituent system components and method steps depicted in the accompanying figures may be implemented in software, or firmware, the actual connections between the system components (or the process steps) may differ depending upon the manner in which the present disclosure is programmed. Given the teachings of the present disclosure provided herein, one of ordinary skill in the related art will be able to contemplate these and similar implementations or configurations of the present disclosure.

The components and devices of the IED 100 can be positioned in various depending on the application or working environment. For example, the components can be positioned in a panel meter, socket meter, switchboard or draw-out type housing, A-base or type A housing. Other housings and mounting schemes are within the scope of this disclosure.

Additionally, the IED 100 can be implanted in various environments. For example, the IED 100 can be implemented in a network, such as public or private network, WAN, LAN, or other type of network. The IED 100 can be connected over the network to various other devices, such as through client/server networks, peer-to-peer networks, mesh networks, etc.

Examples of certain housings, environments, and other features that can be incorporated in the IED 100 are shown and described in U.S. Published Application 2020/0012488, the contents of which are hereby incorporated by reference in their entirety.

In certain implementations, the IED 100 can be connected to and receive a digital input from an external device. The external device can be a utility meter, switch, valve, sensor, alarm or other device associated with a utility system. The external device can be connected with the IED 100 through the I/O ports 118, for example through a hardwired connection. The input from the external device can require processing before being passed to the processing system 106. In certain configurations, a digital input regulator 200 can be used to process the inputs prior to the processing system to make sure a correct current and voltage level of the signals suitable for the processor.

Based on the operating components of the processing system 106, specific voltages or voltage ranges need to be used for the digital inputs. Different external devices can provide different input voltages that may need to be regulated. The IED 100 can contain various digital components, including microprocessors, communication modules, and display drivers, each requiring specific voltage levels. Digital circuits, including processors and A/D converters 104, rely on precise voltage levels to represent logical states (high or low). Variations in supply voltage can cause these logic levels to fluctuate, resulting in unreliable data transmission or even signal corruption.

Voltage regulation ensures that the voltage supplied to the processing system 106 is stable and within the specified operating range, so that the required thresholds are consistently met, maintaining proper communication between the external devices and the processing system 106. Fluctuations or deviations in voltage can cause incorrect signal sampling, leading to data recording errors. Accurate voltage measurement is critical for billing purposes and power quality monitoring.

In certain configurations, an IED can utilize a plurality of voltage regulator circuits, with each circuit associated with a respective input component, such as an A/D converter. Each different voltage regulator will require different circuits components. For example, U.S. Pat. No. 11,366,145 shows a plurality of different voltage regulator circuits used with different inputs of and IED.

In certain implementations, the IED 100 can utilize a current regulating circuit to provide proper current and voltage outputs to the various components. The current regulation circuit can replace the plurality of different voltage regulator circuits. The current regulating circuit can be associated with a single digital input. If the IED 100 can accept multiple digital inputs, multiple current regulating circuits can be used.

Because a current regulating circuit is used to control the output voltage, a single type of current regulating circuit can be used with a broad range of input voltages. This can reduce costs and simplify operation of the IED 100. For example, the current regulating circuit can be used in a range of 3.5V-150V inputs.

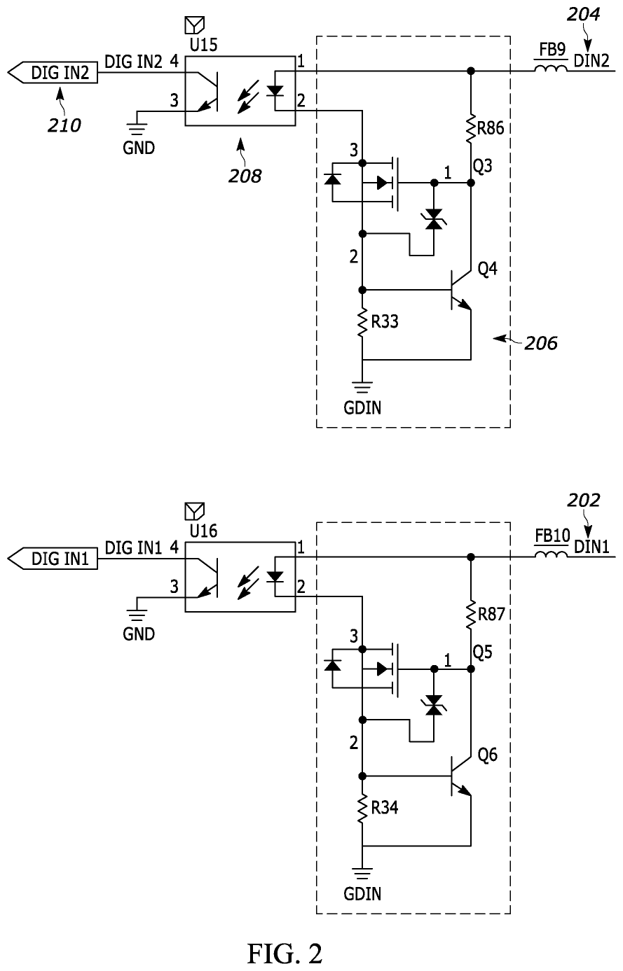

FIG. 2 shows an exemplary configuration of an input for one or more external devices. The input utilizes a first digital input 202 and a second digital input 204. Each of the digital inputs 202, 204 is passed through an inductor to a current regulator 206. In certain configurations the current regulator includes one or more resistors, transistors, and diodes. The arrangement and values of the components can be adjusted based on the range of inputs and the desired output. The current regulator is configured to condition input current and the input voltage from the digital input 202, 204.

The output of the current regulator 206 is connected to an opto-isolator 208. The opto-isolator includes an LED emitter operably connected to a photodetector. The photodetector in the opto-isolator 208 senses the light emitted by the LED and generates a proportional current or voltage on the output side. The opto-isolator 208 provides physical isolation to the downstream components and can prevent any voltage spikes from affecting the processing system 106. The opto-isolator 208 provides a digital signal output 210 that can be provided to the processing system 106.

An IED can also utilize zero-crossing detection to determine and provide a reference point for the frequency input of a connected power system. The frequency signal can also be used to accurately synchronize the meter's internal clock and measurement systems with the incoming AC voltage signal from the power grid. This can ensure accurate power measurements as well as synchronization of data sampling and processing.

A zero-crossing detector (ZCD) circuit 300 is designed to identify the precise moments when the AC voltage waveform crosses the zero-voltage point. In a typical 60 Hz AC system, this occurs twice per cycle-once when transitioning from positive to negative, and once when transitioning from negative to positive. A basic ZCD circuit can compare the input AC voltage to a reference voltage (typically ground or 0V) using a comparator. When the input voltage crosses this reference, the comparator output changes state, producing a square wave that is synchronized with the zero-crossings of the AC input.

Once the zero-crossing points are accurately detected, an IED can use this information in several ways to provide a precise timing reference synchronized to the AC mains. This allows the IED to accurately measure the period of the AC cycle, which is crucial for frequency measurements and detecting any deviations from the nominal 50/60 Hz. By knowing the exact zero-crossing points, the IED can also synchronize its voltage and current sampling processes. This ensures that measurements are taken at consistent points across multiple cycles, improving the accuracy of voltage and current calculations, as well as power factor measurements.

In certain implementations, the IED 100 can utilize a multiplexer which receives the input from each phase from a multi-phase power supply (Va, Vb, Vc, phases). The multiplexer can filter which phase crosses zero first to utilize a single output from the phases to act as the zero-crossing detection point for the system. The use of the MUX allows for a single processing channel, reducing component count and ensuring uniformity in measurements across all phases. In certain configurations, one or more analog multiplexers can be used to provide a single phase output signal.

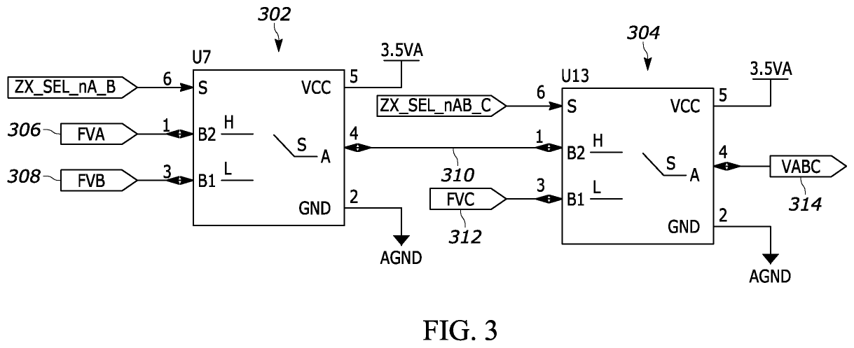

FIG. 3 shows an example of a multiplexer circuit. The multiplexer circuit can be a two-stage multiplexer with a first multiplexer 302 and a second multiplexer 304. The IED 100 can be connected to a multi-phase power supply and receive an input from each phase. These inputs can be conditioned by one or more circuits, for example to reduce the voltage. In certain configurations, the voltage is reduced to approximately 3.5V or less. The voltage can be reduced using one or more step-down transformers, voltage regulators, or a combination thereof. The conditioned input from each phase can be passed to the multiplexer circuit 300.

The first multiplexer 302 can receive the Va input 306 and the Vb input 308. The first multiplexer 302 can select one of the input voltages 306, 308 as a first output 310. In certain configurations the multiplexer will select the first phase to cross zero to provide as the first output 310.

The second multiplexer 304 receives the first output 310 and the Vc input 312. The second multiplexer 302 can select one of the first output 310 and the Vc input 312 as the multiplexer output 314. The multiplexer output 314 can be processed further to obtain a zero-crossing signal. Other configurations can utilize other multiplexer configurations, for example using a single 3-1 multiplexer, to obtain a multiplexer output.

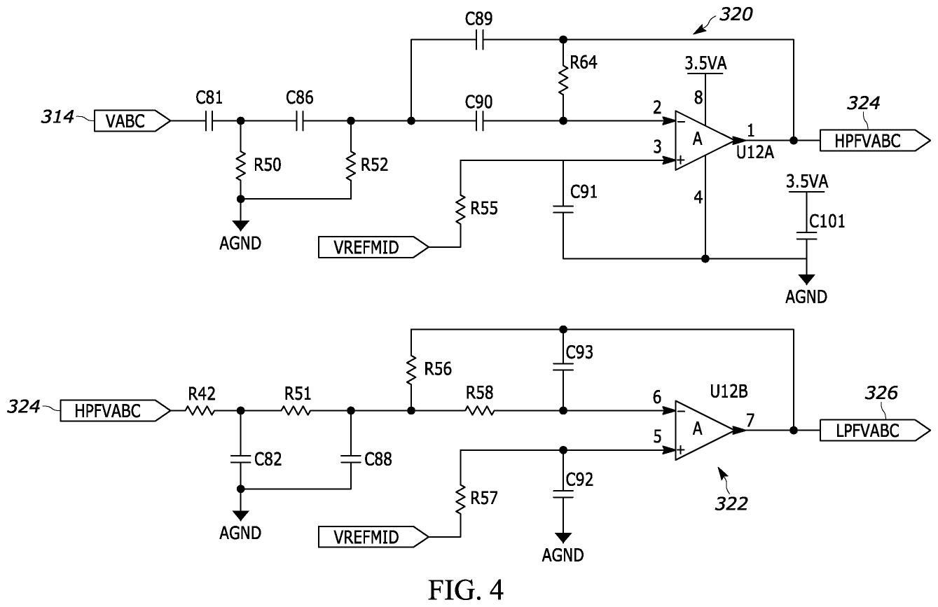

In certain configurations, the multiplexer output 314 can be filtered further before the processing system 106. FIG. 4 shows a band-pass filter arrangement using a high-pass filter 320 and a low-pass filter 322 for processing the multiplexer output 314. The multiplexer output 314 can be passed to the high-pass filter 320 to provide a high-pass output 324. The high-pass output 324 can then be passed through the low-pass filter 322 to provide a HPF-LPF output 326. In certain configurations, the order of this operation can be reversed to obtain the filtered output.

In certain configurations, the multiplexer output 314 is sent to a comparator to obtain a zero-crossing signal. The multiplexer output can be sent directly to a comparator or first filtered through the high-pass filter 320 and low-pass filter 322. The comparator checks the zero-crossing event, and when detected it outputs a zero-crossing signal that can be sent to the processing system. For example, the comparator can output a 1 signal when the event occurs, creating a square-wave output to the processing system 106.

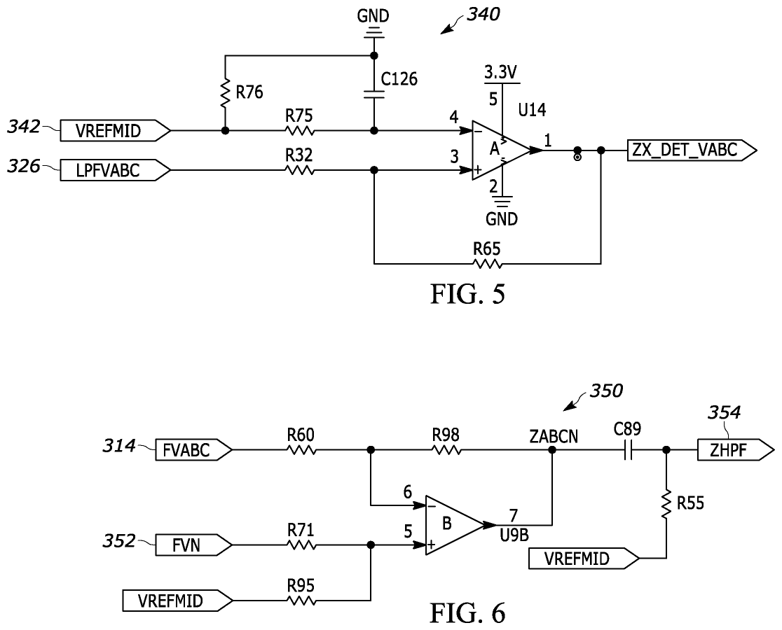

FIG. 5 shows an exemplary configuration of a comparator 340. The comparator 340 receives a reference voltage 342 and the multiplexer output, for example the filtered multiplexer output 326. The comparator is configured to detect a zero-crossing event and output a zero-crossing signal 344. The zero-crossing signal 344 can be sent to the processing system 106.

FIGS. 6-8 show another configuration of the filter and comparator components of the ZCD 300. FIG. 6 shows an exemplary configuration of a differentiator circuit with a high-pass filter 350. The multiplexer output 314 and the neutral signal (Vn) are input to a differential amplifier to obtain the difference between the selected phase signal and the neutral signal (Va-Vn, Vb-Vn, or Vc-Vn).

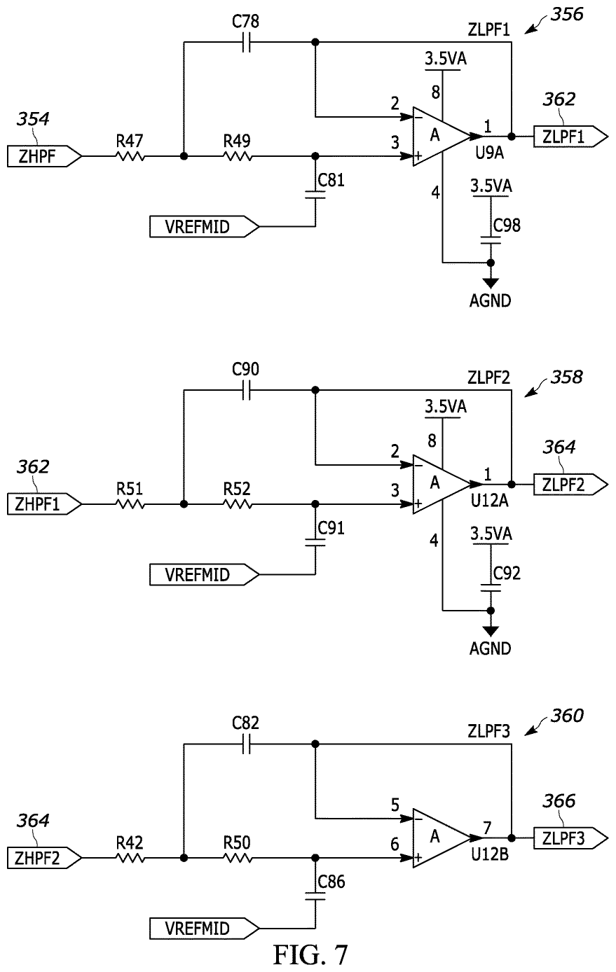

The output 354 of the circuit 350 can then be passed to one or more low-pass filters. FIG. 7 shows an exemplary configuration of a series of three low-pass filters 356, 358, 360. In certain configurations, the low pass-filters 356, 358, 360 have a Sallen-Key configuration. The output 362 of the first filter 356 is input to the second filter 358. The output 364 of the second filter is then passed to the third filter 360. The output 366 of the third filter 360 can then be provided to a comparator to obtain a zero-crossing signal.

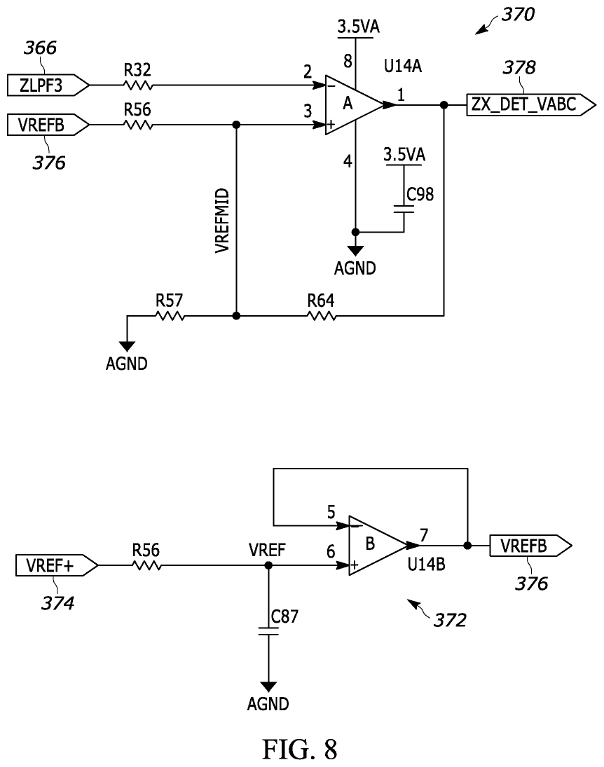

FIG. 8 shows an exemplary configuration of a comparator circuit 370 and a voltage buffer circuit 372. The voltage buffer circuit 372 receives the reference voltage 374 and provides a buffered reference voltage 376. This buffered reference voltage 376 is provided to the comparator 370 so that any current drained into the buffered voltage 376 from the comparator 370 does not affect the reference voltage 374.

The buffered reference voltage 376 and the filtered multiplexer output 366 can be provided to the comparator 370 to obtain a zero-crossing signal 378 as described above.

The foregoing detailed description has been provided for the purpose of explaining the general principles and practical application, thereby enabling others skilled in the art to understand the disclosure for various configurations and implementations, and with various modifications as are suited to the particular uses contemplated. This description is not necessarily intended to be exhaustive or to limit the disclosure to what is disclosed. Any of the configurations and/or elements disclosed herein may be combined with one another to form various additional embodiments not specifically disclosed. Accordingly, additional configurations and implementations are possible and are intended to be encompassed within this specification and the scope of the appended claims. The specification describes specific examples to accomplish a more general goal that may be accomplished in another way.

As used in this application, the terms “front,” “rear,” “upper,” “lower,” “upwardly,” “downwardly,” and other orientational descriptors are intended to facilitate the description of the exemplary embodiments of the present disclosure, and are not intended to limit the structure of the exemplary embodiments of the present disclosure to any particular position or orientation. Terms of degree, such as “substantially” or “approximately” are understood by those of ordinary skill to refer to reasonable ranges outside of the given value, for example, general tolerances associated with manufacturing, assembly, and use of the described embodiments. Unless specified or limited otherwise, the terms “mounted,” “connected,” “supported,” and “coupled” and variations thereof are used broadly and encompass both direct and indirect mountings, connections, supports, and couplings. The words “member,” “component,” “module,” “mechanism,” “element,” “device,” and the like are not a substitute for the word “means.” As such, no claim element should be construed as a means plus function unless the element is expressly recited using the phrase “means for.”

Functionality described herein may be implemented by any combination of hardware, software, or firmware. Functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way but may also be configured in ways that are not explicitly listed.

Certain electrical components are generally shown and described in terms of their functions or end results as it would be understood by one of ordinary skill viewing this disclosure that the exact structure, connections, and components can be varied to achieve the desired results. In addition, certain implementation may include hardware, software, and electronic components or modules that, for purposes of discussion, may be illustrated and described as if most of the components were implemented solely in hardware. However, one of ordinary skill in the art, and based on a reading of this disclosure would recognize that in certain configurations the electronic-based aspects may be implemented in software (e.g., stored on non-transitory computer-readable medium) executable by one or more processing units, such as any combination of one or more of a general-purpose processor, microprocessor, DSP, FPGA, application specific integrated circuits (“ASICs”), and/or other programmable logic device.. As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

1. A utility meter comprising:
a housing;
at least one sensor connected to the housing and configured to be connected to a utility system, the at least one sensor configured for measuring at least one parameter of the utility system and generating at least one analog signal indicative of the at least one parameter;
at least one analog to digital converter connected to the at least one sensor, the at least one analog to digital converter configured to receive the at least one analog signal and convert the at least one analog signal to an at least one digital signal to obtain measured data;
a processing system including one or more processors, the processing system configured for receiving the at least one digital signal;
an input port configured to receive a digital input from an external device; and
an input regulator configured to receive the digital input and condition the digital input, wherein the input regulator includes a current regulator circuit.

2. The utility meter of claim 1, wherein the current regulator produces a regulated digital input that is sent to the processing system.

3. The utility meter of claim 1, wherein the input regulator is configured to handle input voltages in the range of 3.5 v-150 v.

4. The utility meter of claim 1, wherein the input regulator includes an opto-isolator.

5. The utility of claim 1, wherein the input port is configured to receive a hardwired connection.

6. The utility meter of claim 1, wherein the input port is configured to receive a plurality of digital inputs from one or more external devices, and wherein the input regulator includes a respective current regulator circuit associated with each of the plurality of digital inputs.

7. The utility meter of claim 1, wherein the input regulator further includes an opto-isolator connected to an output of the current regulator circuit, the opto-isolator configured to electrically isolate the processing system from the digital input and to provide a digital signal output to the processing system.

8. The utility meter of claim 1, further comprising a zero-crossing circuit in communication with the processing system, the zero-crossing circuit including a multiplexer circuit configured to receive a three-phase input and produce a single multiplexer output, and a comparator configured to receive the multiplexer output and produce a zero-crossing signal for the processing system.

9. A utility meter comprising:
a housing;
at least one sensor connected to the housing and configured to be connected to a utility system, the at least one sensor configured for measuring at least one parameter of the utility system and generating at least one analog signal indicative of the at least one parameter;
at least one analog to digital converter connected to the at least one sensor, the at least one analog to digital converter configured to receive the at least one analog signal and convert the at least one analog signal to an at least one digital signal to obtain measured data;
a processing system including one or more processors, the processing system configured for receiving the at least one digital signal;
a zero-crossing circuit in communication with the processing system, wherein the zero-crossing circuit includes a multiplexer circuit configured to receive a three-phase input and produce a single multiplexer output.

10. The utility meter of claim 9, wherein the multiplexer circuit includes a first multiplexer and a second multiplexer.

11. The utility meter of claim 10, wherein the first multiplexer is configured to receive a first phase of a circuit and a second phase of a circuit and produce a first output and the second multiplexer is configured to receive the first output and a third phase and produce the multiplexer output.

12. The utility meter of claim 9, wherein the zero-crossing circuit includes a band-pass filter configured to receive the multiplexer output and provide a filtered output

13. The utility meter of claim 12, wherein the band pass filter includes a high pass filter and a plurality of sequential low pass filters.

14. The utility meter of claim 12, wherein the zero-crossing circuit
includes a comparator configured to receive the filtered output and produce a zero-crossing signal 15. The utility meter of claim 14, wherein the comparator receives a reference voltage.

16. The utility meter of claim 15, wherein the reference voltage is a buffered reference voltage received from a voltage buffer circuit.

17. A method of determining a zero-crossing event from a 3-phase voltage signal in a utility meter comprising:
receiving a three-phase power input having an input voltage and an input frequency;
inputting the first phase and the second phase to a first multiplexer;
selecting, by the first multiplexer, one of the first phase and the second phase as a first output;
inputting the first output and the third phase to a second multiplexer;
selecting, by the second multiplexer, one of the third phase and the first output as a multiplexer output;
providing the multiplexer output to a comparator to obtain a zero-crossing signal; and
providing the zero-crossing signal to a processing system.

18. The method of claim 17, further comprising conditioning the three-phase power input to transform the input voltage to a reduced voltage prior to inputting the first phase, second phase, and third phase to the first and second multiplexers, respectively.

19. The method of claim 17, wherein the multiplexer output is passed through a high-pass filter and a low-pass filter prior to the comparator.

20. The method of claim 17, further comprising obtaining a difference between the multiplexer output and a neutral signal using a differentiator circuit including a high-pass filter, passing an output of the differentiator circuit through a plurality of sequential low-pass filters to obtain a filtered output, and providing the filtered output and a buffered reference voltage to the comparator to obtain the zero-crossing signal.
